(19) United States
(12) Patent Application Publication
(10) Pub. No.: US 2011/0128795 A1
(43) Pub. Date: Jun. 2, 2011

(54) SEMICONDUCTOR MEMORY DEVICE HAVING SENSE AMPLIFIER

(76) Inventors: Myoung-Jin LEE, Gyeonggi-do (KR); Hyung-Sik Won, Gyeonggi-do (KR); Ki-Myung Kyung, Gyeonggi-do (KR); Joong-Ho Lee, Gyeonggi-do (KR)

(21) Appl. No.: 12/649,393

(22) Filed: Dec. 30, 2009

(30) Foreign Application Priority Data
Nov. 30, 2009 (KR) 10-2009-0117426

(51) Int. Cl. G11C 7/10; G11C 7/02; H03F 3/45

(52) U.S. Cl. 365/189.05; 365/207; 327/52

(57) ABSTRACT

A sense amplifier prevents a reduction in sensing margin occurring when data forms an island pattern. The sense amplifier includes a first inverter having an input terminal connected to a bit line and an output terminal connected to a bar bit line, and a second inverter having an input terminal connected to the bar bit line and an output terminal connected to the bit line. The first and second inverters are configured to receive a pull-up voltage through different pull-up voltage lines, respectively.

### CROSS-REFERENCE TO RELATED APPLICATIONS

The present application claims priority of Korean Patent Application No. 10-2009-0117426, filed on Nov. 30, 2009, which is incorporated herein by reference in its entirety.

### BACKGROUND OF THE INVENTION

Exemplary embodiments of the present invention relate to a semiconductor memory device, and more particularly, to a sense amplifier and a semiconductor memory device having the same.

A latch circuit is widely used as an amplifier to amplify a difference in a voltage between two lines. A bit line sense amplifier (BLSA) is provided as a representative example of the latch circuit used as an amplifier.

FIG. 1 is a circuit diagram illustrating a bit line sense amplifier of a conventional semiconductor memory device.

When data is read from a cell array 100, a voltage level of a bit line BL is changed by the read data, which makes voltage levels of a bit line pair BL and BLB to be different. In this state, since the change in voltage level of the bit line BL is relatively small, bit line sense amplifiers 110 and 120 are used to amplify the difference between the voltage levels of the bit line pair BL and BLB.

The bit line sense amplifiers 110 and 120 are configured as a latch circuit for amplifying a difference between voltages of a bit line pair BL0 and BLB0 or a difference between voltages of a bit line pair BL2 and BLB2, respectively. The latch circuit includes two inverters 111 and 112 or 121 and 122. During the amplification operation of the bit line sense amplifiers 110 and 120, signal SAP and signal SAN change to a high level so that transistors T1 and T2 are turned on. As a result, a pull-up voltage line RTO changes to the level of a power supply voltage VDD, and a pull-down voltage line SB changes to the level of a ground voltage VSS. The inverter pairs, 111 and 112, and 121 and 122, receiving a driving voltage through the voltage lines RTO and SB amplify a voltage difference between the bit line pairs, BL0 and BLB0, and BL2 and BLB2, respectively.

For example, when the voltage level of the bit line BL0 is higher than that of the bar bit line BLB0, the bit line sense amplifier 110 changes the bit line BL0 to the level of the power supply voltage VDD, and changes the bar bit line BLB0 to the level of the ground voltage VSS. On the other hand, when the voltage level of the bar bit line BLB0 is higher than that of the bit line BL0, the bit line sense amplifier 110 changes the bar bit line BLB0 to the level of the power supply voltage VDD, and changes the bit line BL0 to the level of the ground voltage VSS.

FIG. 2 is a circuit diagram for illustrating an occurrence of a sensing fail in the conventional semiconductor memory device.

When “H” (or “L”) data is written in a specific cell and “H” (or “L”) data are also written in the neighboring cells, that is, when data of a specific cell is identical to those of the neighboring cells, the data forms a solid pattern with data of the neighboring cells. On the other hand, when “H” (or “L”) data is written in a specific cell and “L” (or “H”) data are written in the neighboring cells, that is, when data of a specific cell is different from those of the neighboring cells, the data forms an island pattern with data of the neighboring cells.

FIG. 2 illustrates a case in which data of the rightmost cell, indicated as “island”, among cells connected to a word line WLN forms an island pattern. In this case, it is more likely that data stored in the cell forming an island pattern may be sensed incorrectly. For example, a coupling (e.g., capacitive coupling) occurs between the word line WLN and cells connected to the word line WLN. In this case, since the “H” data are stored in most of the cells connected to the word line WLN as shown, the voltage of the word line WLN increases. Furthermore, the increasing voltage of the word line WLN effects the cell forming an island pattern so that the voltage of the island pattern cell increases. Accordingly, it is more likely that the “L” data stored in the island pattern cell is incorrectly sensed as “H” data. In other words, a sensing margin decreases in the case of the island pattern.

FIG. 2 illustrates a case in which the data of the island pattern cell is “L” data. However, even when the data of the island pattern cell is “H” data and the data of the neighboring cells are “L” data, it is more likely that the data of the island pattern cell is incorrectly sensed as “L” data.

On the other hand, when data forms a solid pattern, the neighboring data are each strengthened by the coupling effect. That is, the potential of “H” data further increases, and the potential of “L” data further decreases. Thus, when the data forms a solid pattern, a sensing margin increases.

In summary, when data forms a sold pattern, the sensing margin increases, and when data forms an island pattern, the sensing margin decreases.

### SUMMARY OF THE INVENTION

An embodiment of the present invention is directed to a sense amplifier which prevents a reduction in sensing margin occurring when data forms an island pattern. The sense amplifier can improve a write recovery time tWR while preventing the reduction in the sensing margin

In accordance with an embodiment of the present invention, a sense amplifier includes a first inverter having an input terminal connected to a bit line and an output terminal connected to a bar bit line, and a second inverter having an input terminal connected to the bar bit line and an output terminal connected to the bit line, where the first and second inverters are configured to receive a pull-up voltage through different pull-up voltage lines, respectively.

The first inverter may be configured to receive the pull-up voltage from a first pull-up voltage line and the second inverter may be configured to receive the pull-up voltage from a second pull-up voltage line. The first and second pull-up voltage lines are commonly connected to a pull-up power supply circuit, and supply the pull-up voltage through different paths.

In accordance with another embodiment of the present invention, a sense amplifier includes a first inverter having an input terminal connected to a bit line and an output terminal connected to a bar bit line, and a second inverter having an input terminal connected to the bar bit line and an output terminal connected to the bit line, wherein the first and second inverters are configured to receive a pull-down voltage through pull-down voltage lines.

The first inverter may be configured to receive the pull-down voltage from a first pull-down voltage line and the second inverter may be configured to receive the pull-down voltage from a second pull-down voltage line. The first and second pull-down voltage lines are commonly connected to a pull-down power supply circuit, and supply the pull-down voltage through different paths.

In accordance with yet another embodiment of the present invention, a semiconductor memory device includes a first sense amplifier including first and second inverters constituting a latch between a first bit line and a first bar bit line, and a second sense amplifier including third and fourth inverters constituting a latch between a second bit line and a second bar bit line, wherein the first and second inverters are configured to receive a voltage through different voltage lines, respectively, and the third and fourth inverters are configured to receive the voltage through different voltage lines, respectively.

The first inverter may be coupled to a first pull-up voltage line and a first pull-down voltage line, the second inverter may be coupled to a second pull-up voltage line and a second pull-down voltage line, the third inverter may be coupled to the first pull-up voltage line and the first pull-down voltage line, and the fourth inverter may be coupled to the second pull-up voltage line and the second pull-down voltage line.

The semiconductor memory device may further include a pull-up power supply circuit and a pull-down power supply circuit, wherein pull-up voltage lines are connected to the pull-up power supply circuit and are configured to supply a pull-up voltage through different paths and pull-down voltage lines are connected to the pull-down power supply circuit and are configured to supply a pull-down voltage through different paths.

In accordance with still another embodiment of the present invention, a semiconductor memory device includes a first voltage line configured to supply a voltage for driving the bit line and a second voltage line configured to supply a voltage for driving the bar bit line, a switch configured to connected the first and second voltage lines to each other in response to a control signal, and a bit line sense amplifier configured to amplify a difference in the voltage of the bit line and the voltage of the bar bit line.

The bit line and the bar bit line are configured to be driven by a same voltage supplied through different paths.

### BRIEF DESCRIPTION OF THE DRAWINGS

FIG. 1 is a circuit diagram illustrating a bit line sense amplifier of a conventional semiconductor memory device.

FIG. 2 is a diagram explaining a situation in which a sensing fail occurs in the conventional semiconductor memory device.

FIG. 3 illustrates a semiconductor memory device in accordance with an embodiment of the present invention.

FIG. 4A is a diagram illustrating a case in which separated voltage lines RT01 and RT02 are connected to a pull-up power supply circuit 330 through one contact.

FIG. 4B is a diagram illustrating a case in which the separated voltage lines RT01 and RT02 are connected to the pull-up power supply circuit 330 through different contacts.

FIG. 4C is a diagram illustrating a case in which a PMOS transistor constituting the pull-up power supply circuit 330 has a fingering structure and the separated voltage lines RT01 and RT02 are connected to the pull-up power supply circuit 330 through different contacts.

FIG. 5 illustrates a semiconductor memory device in accordance with another embodiment of the present invention.

FIG. 6 is an internal configuration diagram of sense amplifiers 510 and 520 of FIG. 5.

FIG. 7 illustrates a semiconductor memory device in accordance with further embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

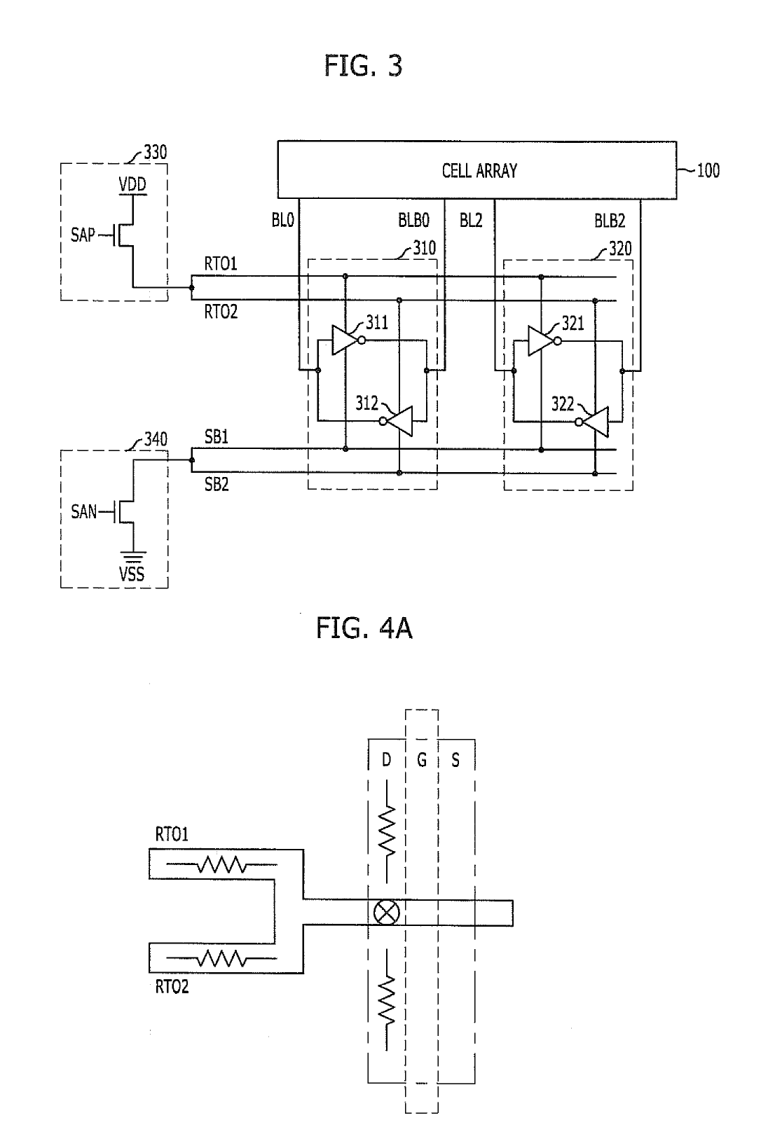

FIG. 3 illustrates a semiconductor memory device in accordance with an embodiment of the present invention.

The semiconductor memory device includes a cell array 100, a first sense amplifier 310, a second sense amplifier 320, a pull-up power supply circuit 330, and a pull-down power supply circuit 340.

The first sense amplifier 310 includes two inverters 311 and 312 constituting a latch between bit line BL0 and bar bit line BLB0. The inverter 311 receives supply voltages VDD and VSS through voltage lines RT01 and SB1, respectively, and the inverter 312 receives supply voltages VDD and VSS through voltage lines RT02 and SB2, respectively. More specifically, the first pull-up voltage line RT01 and the first pull-down voltage line SB1 are used to supply a driving voltage to the inverter 311 as appropriate, and the second pull-up voltage line RT02 and the second pull-down voltage line 5132 are used to supply a driving voltage to the inverter 312 as appropriate. That is, a driving voltage for amplifying the bar bit line BLB0 is supplied through the first pull-up voltage line RT01 and the first pull-down voltage line SB1 as appropriate, and a driving voltage for amplifying the bit line BL0 is supplied through the second pull-up voltage line RT02 and the second pull-down voltage line SB2 as appropriate.

The second sense amplifier 320 includes two inverters 321 and 322 constituting a latch between bit line BL2 and bar bit line BLB2. The inverter 321 receives supply voltages VDD and VSS through voltage lines RT01 and SB1, respectively, and the inverter 322 receives supply voltages VDD and VSS through voltage lines RT02 and SB2, respectively. More specifically, the first pull-up voltage line RT01 and the first pull-down voltage line SB1 are used to supply a driving voltage to the inverter 321 as appropriate, and the second pull-up voltage line RT02 and the second pull-down voltage line SB2 are used to supply a driving voltage to the inverter 322 as appropriate. That is, a driving voltage for amplifying the bar bit line BLB2 is supplied through the first pull-up voltage line RT01 and the first pull-down voltage line SB1 as appropriate, and a driving voltage for amplifying the bit line BL2 is supplied through the second pull-up voltage line RT02 and the second pull-down voltage line SB2 as appropriate.

The pull-up power supply circuit 330 supplies a power supply voltage VDD to the pull-up voltage lines RT01 and RT02 as a pull-up voltage in response to a signal SAP. While both of the first and second pull-up voltage lines RT01 and RT02 connected to the pull-up power supply circuit 330 supply a same pull-up voltage (that is, the power supply voltage VDD), the first and second pull-up voltage lines RT01 and RT02 may supply the pull-up voltage by using different paths as shown. The pull-up power supply circuit 330 may include a PMOS transistor as illustrated in FIG. 3.

The pull-down power supply circuit 340 supplies a ground voltage VSS to the pull-down voltage lines SB1 and SB2 in response to a signal SAN. While both of the first and second pull-down voltage lines SB1 and SB2 connected to the pull-down power supply circuit 340 supply a same pull-down voltage (that is, the ground voltage VSS), the first and second pull-down voltage lines SB1 and SB2 may supply the pull-down voltage by using different paths as shown. The pull-down power supply circuit 340 may include an NMOS transistor as illustrated in FIG. 3.

According to an exemplary embodiment of the present invention, a voltage is supplied to the inverter pairs (311 and 312 or 321 and 322) of the sense amplifiers (310 or 320) through different voltage supply lines. That is, the voltage supply lines RT02 and SB2 to provide supply voltages used in amplifying the bit lines BL0 and BL2 are separated from the voltage lines RT01 and SB1 to provide supply voltages used in amplifying the bar bit lines BLB0 and BLB2. In such a configuration, it is possible to improve a sensing margin when data forms an island pattern.

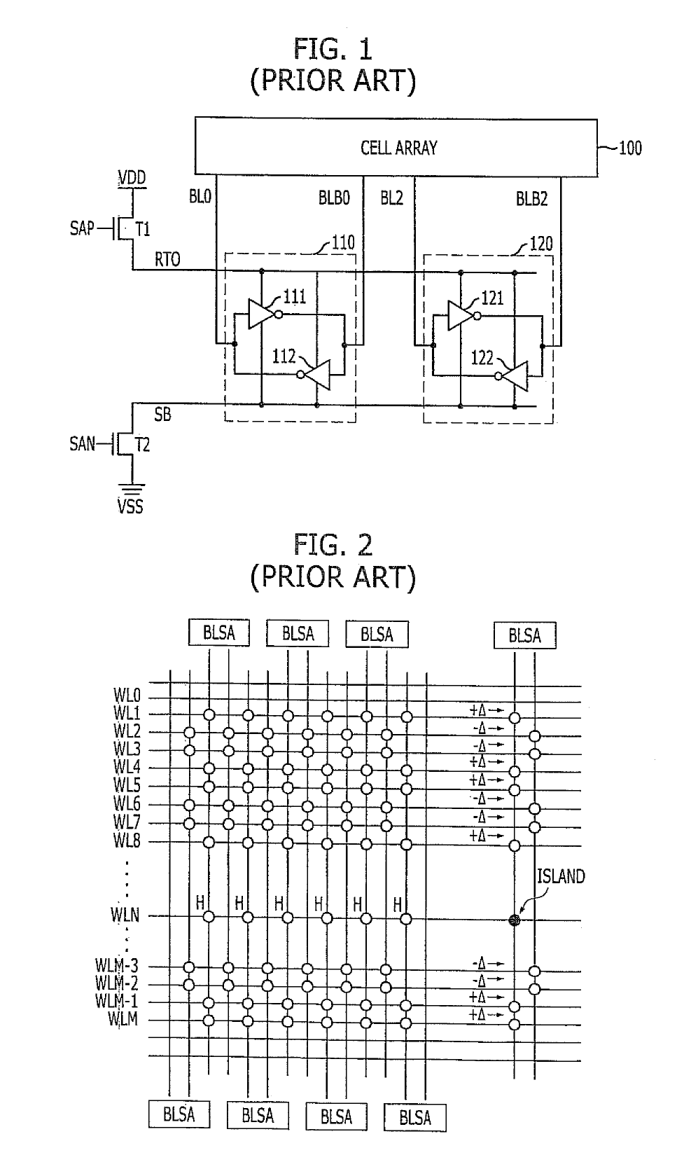

For example, first, assume that “L” data is loaded only on the bit line pair BL0 and BLB0 and “H” data is loaded on the other bit line pairs BL1 to BLN and BLB1 to BLBN while FIG. 3 illustrates the bit line pair BL2 and BLB2 only. In this case, the sense amplifiers for amplifying the bit line pairs BL1 to BLN and BLB1 to BLBN receive a voltage through the first pull-down voltage line SB1 and the second pull-up voltage line RT02. While the sense amplifiers include other sense amplifiers, only the sense amplifier 320 is shown in FIG. 1 Therefore, a large amount of current flows through the first pull-down voltage line SB1 and the second pull-up voltage line RT02. As a result, relatively significant voltage drops may occur through the first pull-down voltage line SB1 and the second pull-up voltage line RT02.

On the other hand, the sense amplifier 310 receives a voltage through the second pull-down voltage line SB2 and the first pull-up voltage line RT01 as appropriate. Since the second pull-down voltage line SB2 and the first pull-up voltage line RT01 provide supply voltages to the sense amplifier 310 only, a relatively small amount of current flows in the second pull-down voltage line SB2 and the first pull-up voltage line RT01, and a voltage drop is relatively small. Thus, the sense amplifier 310 receives a voltage with a relatively strong driving power in comparison with the other sense amplifiers.

As such, the sense amplifier 310 which amplifies island pattern data receives a voltage with a relatively strong driving power, and the other sense amplifiers receive a voltage with a relatively weak driving power. Such difference in driving powers tend to increase the sensing margin of the sense amplifier 310 which amplifies the island pattern data and somewhat decrease the sensing margin of the other sense amplifiers which amplify solid pattern data. However, since a sufficient sensing margin already exists in the case of the solid pattern data, such a small decrease in the sensing margin of the other sense amplifiers does not change the final output.

As described in the background of the invention, the coupling between the bit lines BL and BLB and the word line WL increases the sensing margin of the solid pattern data and decreases the sensing margin of the island pattern data. In the exemplary embodiment of the present invention, however, the separation of the voltage lines tends to increase the sensing margin of the island pattern data, and decrease the sensing margin of the solid pattern data. Therefore, it is possible to adjust the sensing margins of the island pattern data and the solid pattern data to substantially the same level by offsetting sensing margin changes from the coupling between the bit lines BL and BLB and the word line WL. According to the exemplary embodiment of the present invention, the sensing margin for the island pattern data which normally is the poorest in comparison to other sensing margins may be increased to improve the overall sensing margin of the memory device, where the overall sensing margin of the memory device corresponds to the poorest sensing margin.

FIG. 3 illustrates a case in which the pull-up voltage lines RT01 and RT02 and the pull-down voltage lines SB1 and SB2 which are connected to the inverters 311, 312, 321, and 322 within the sense amplifiers 310 and 320 are separated. However, it would be apparent to a person of ordinary skill in the art that only one of the set of the pull-up voltage lines RT01 and RT02 and the set of the pull-down voltage lines SB1 and SB2 may also be formed of separate voltage lines depending on different design needs. While the exemplary embodiment of the present invention has been illustrated in connection with a folded bit line structure, the exemplary embodiment of the present invention may also be applied to an open bit line structure.

The sets of separated voltage lines RT01 and RT02 or SB1 and SB2 may each be connected to power supply circuit 330 and 340 in a variety of different methods. Hereafter, the connection method will be described.

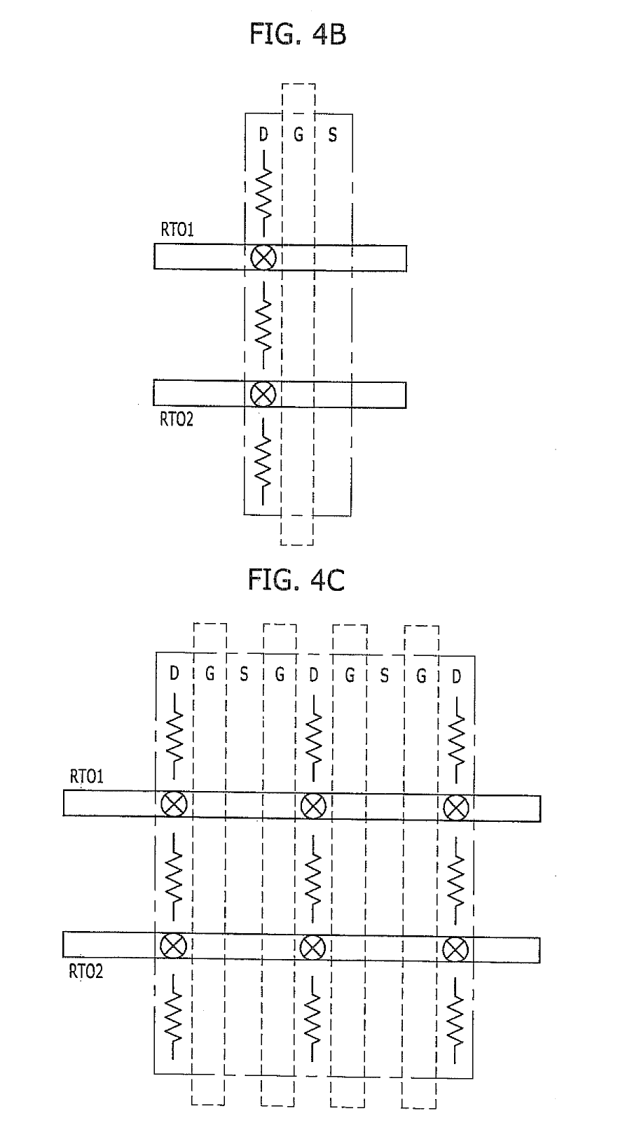

FIG. 4A is a diagram illustrating a case in which the separated voltage lines RT01 and RT02 are connected to the pull-up power supply circuit 330 through one contact. Referring to FIG. 4A, it can be seen that contact \textcircled{x} is formed in a drain region D of a PMOS transistor, and the first and second pull-up voltage lines RT01 and RT02 are connected through the contact \textcircled{x}. For illustration purposes, a resistor symbol in FIG. 4A represents a resistor component including a resistor component of the drain region D.

FIG. 4B is a diagram illustrating a case in which the separated voltage lines RT01 and RT02 are connected to the pull-up power supply circuit 330 through different contacts. Referring to FIG. 4B, two contacts \textcircled{x} are formed in the drain region D of the PMOS transistor. The first pull-up voltage line RT01 is connected to one contact \textcircled{x}, and the second pull-up voltage line RT02 is connected to the other contact \textcircled{x}. As such, when the first and second pull-up voltage lines RT01 and RT02 are connected to the drain region D of the PMOS transistor through the different contacts \textcircled{x}, a difference in voltage drop through the first and second pull-up voltage lines RT01 and RT02 may be induced more drastically. Although the contacts \textcircled{x} are formed in the same drain region D, the positions of the contacts \textcircled{x} are different from each other. Therefore, current paths through the contacts are formed differently within the drain region D, and the difference in voltage drop is maximized.

That is, when the separated voltage lines RT01 and RT02 are connected to the pull-up power supply circuit 330 through different contacts \textcircled{x}, the sensing margin of the island pattern data may be increased further than when the separated voltage lines RT01 and RT02 are connected through just one contact \textcircled{x}.

FIG. 4C is a diagram illustrating a case in which a PMOS transistor constituting the pull-up power supply circuit 330 has a fingering structure and the separated voltage lines RT01 and RT02 are connected to the pull-up power supply circuit 330 through different contacts. Referring to FIG. 4C, the PMOS transistor has a fingering structure, and two contacts \textcircled{x} are formed in each drain region of the fingering structure. The first pull-up voltage line RT01 is connected to upper contacts \textcircled{x}, and the second pull-up voltage lines RT02 is connected to lower contacts \textcircled{x}. When the PMOS transistor has a fingering structure, the number of fingers may be controlled to adjust the extent of difference in voltage drop between the first and second pull-up voltage lines RT01 and RT02.

In reference to FIGS. 4A to 4C, the variety of methods by which the separated pull-up voltage lines RT01 and RT02 may be connected to the PMOS transistor composing the pull-up power supply circuit 330 have been described. According to an example, the pull-up power supply circuit 330 may be implemented by a plurality of PMOS transistors connected in parallel. In this case, one or more of the PMOS transistors may be connected to the pull-up voltage lines RT01 and RT02 as illustrated in FIGS. 4A, 4B and 4C. That is, it is possible to adjust the difference in voltage drops through the first and second pull-up voltage lines RT01 and RT02 by using various combinations of the connection methods shown in FIGS. 4A-4C.

The connection of the pull-down voltage lines SB1 and SB2 to the pull-down power supply circuit 340 may be performed in the same manner as the pull-up voltage lines RT01 and RT02 are connected to the pull-up power supply circuit 330 in FIGS. 4A to 4C. A difference exists however in that an NMOS transistor is used in the pull-down power supply circuit 340 in place of the PMOS transistors shown in FIGS. 4A to 4C.

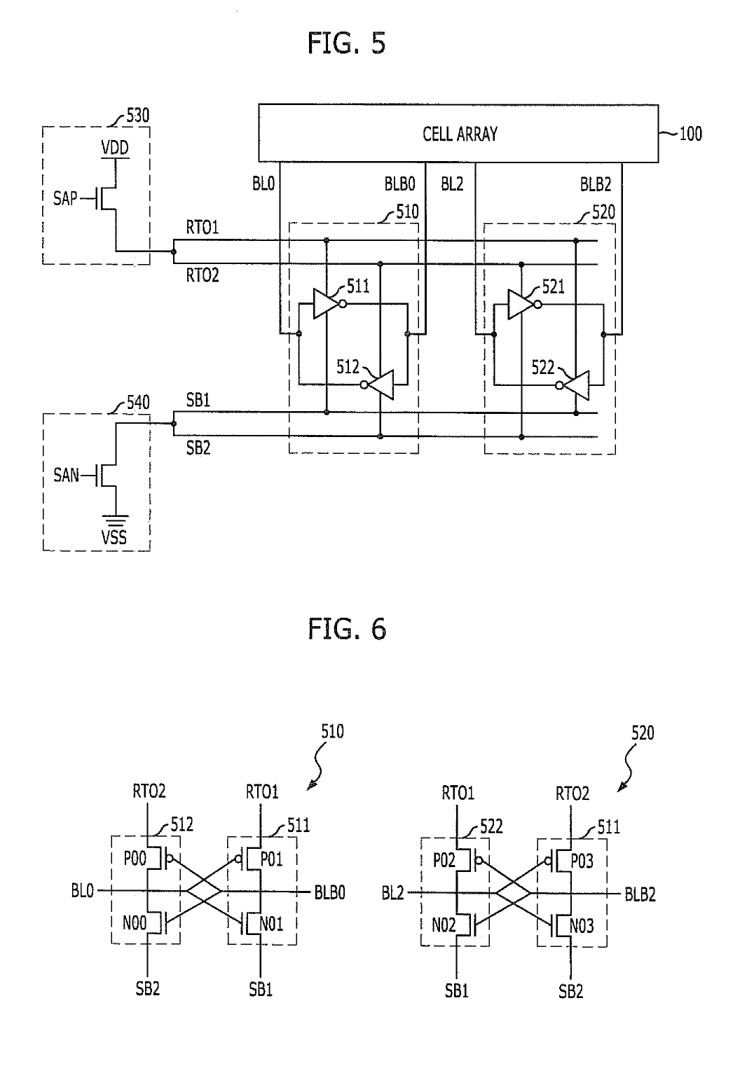

FIG. 5 illustrates a semiconductor memory device in accordance with another embodiment of the present invention.

In the embodiment of the present invention, the set of two inverters 511 and 512 or the set of two inverters 521 and 522 composing sense amplifier 510 or sense amplifier 520 receives a supply voltage from separate voltage lines RT01 and RT02 and separate voltage lines SB1 and SB2, similar to the above described embodiment of the present invention. A difference exists in that the adjacent sense amplifiers 510 and 520 receive supply voltages in a different manner.

In the first sense amplifier 510, the first pull-up voltage line RT01 and the first pull-down voltage line SB1 each supply a voltage to the inverter 511, and the second pull-up voltage line RT02 and the second pull-down voltage line SB2 each supply a voltage to the inverter 512. That is, a driving voltage for amplifying a bar bit line BLB0 is supplied through the first pull-up voltage line RT01 and the first pull-down voltage line SB1 as appropriate, and a driving voltage for amplifying a bit line BL0 is supplied through the second pull-up voltage line RT02 and the second pull-down voltage line SB2 as appropriate.

In the second sense amplifier 520, the first pull-up voltage line RT01 and the first pull-down voltage line SB1 each supply a voltage to the inverter 522, and the second pull-up voltage line RT02 and the second pull-down voltage line SB2 each supply a voltage to the inverter 521. That is, a driving voltage for amplifying a bit line BL2 is supplied through the first pull-up voltage line RT01 and the first pull-down voltage line SB1 as appropriate, and a driving voltage for driving a bar bit line BLB2 is supplied through the second pull-up voltage line RT02 and the second pull-down voltage line SB2 as appropriate.

In the first sense amplifier 510, the first pull-up voltage line RT01 and the first pull-down voltage line SB1 supply voltages used for amplifying the bar bit line BLB0. In the second sense amplifier 520, however, the second pull-up voltage line RT02 and the second pull-down voltage line SB2 supply voltages used for amplifying the bar bit line BLB2. Similarly, in the first sense amplifier 510, the second pull-up voltage line RT02 and the second pull-down voltage line SB2 supply voltages used for amplifying the bit line BL0. In the second sense amplifier 520, however, the first pull-up voltage line RT01 and the first pull-down voltage line SB1 supply voltages used for amplifying the bit line BL2.

When the voltage is supplied in such an alternate manner between the adjacent sense amplifiers 510 and 520, it is possible to improve the sensing margin of island pattern data, because the voltage lines in each of the set of the voltage lines RT01 and RT02 and the set of the voltage lines SB1 and SB2 are separated from each other.

FIG. 6 is an internal configuration diagram of the sense amplifiers 510 and 520 of FIG. 5.

Referring to FIG. 6, each of the inverters 511, 512, 521, and 522 constituting the sense amplifiers 510 and 520 include one PMOS transistor (P00, P01, P02, or P03) and one NMOS transistor (N00, N01, N02, or N03).

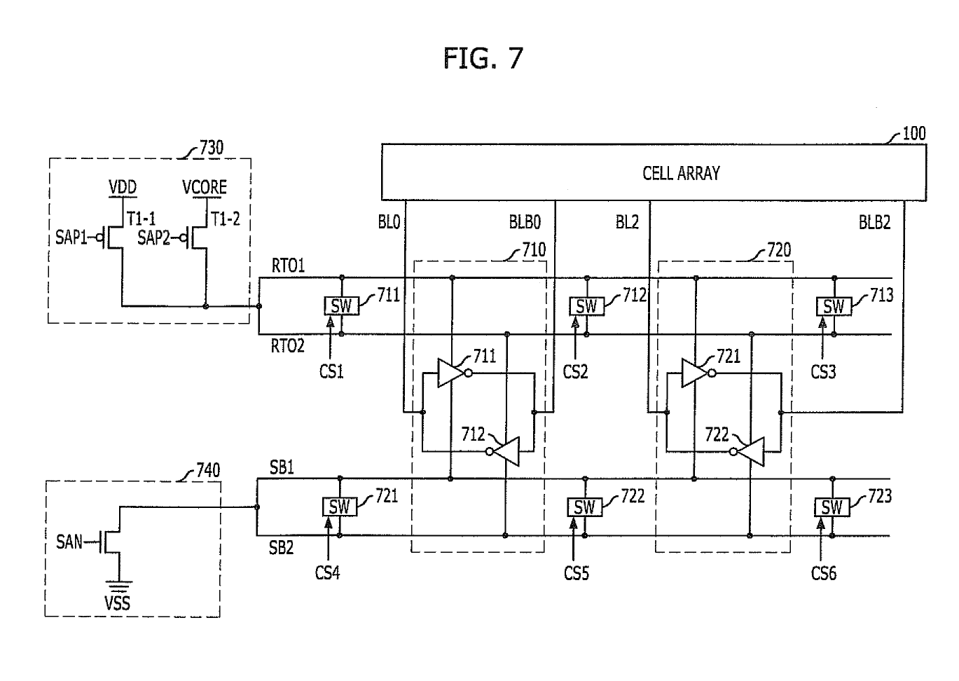

FIG. 7 illustrates a semiconductor memory device in accordance with further embodiment of the present invention.

The semiconductor memory device includes a cell array 100, a first sense amplifier 710, a second sense amplifier 720, a pull-up power supply circuit 730, and a pull-down power supply circuit 740. Similar to the above described embodiment of the present invention, the set of two inverters 711 and 712 or the set of two inverters 721 and 722 composing the sense amplifier 710 or sense amplifier 720 receives a supply voltage from separate voltage lines RT01 and RT02 and separate voltage lines SB1 and SB2. A difference exists in that the semiconductor memory device further includes first switches 711-713 and second switches 721-721

As described above, pull-up and pull-down voltage lines are implemented with separate voltage lines RT01 and RT02 and separate voltage lines SB1 and SB2, respectively. Therefore, it brings about offsets with respect to the sensing margins between data, which makes it possible to increase the sensing margin of the island pattern data. However, the caused offsets may increase a write recovery time tWR in a write operation of the semiconductor memory device. The first switches 711-713 and the second switches 721-723 are further included to address this concern.

The first switches 711-713 connect first and second pull-up voltage lines RT01 and RT02 with each other in response to control signals CS1-CS3. When the first switches 711-713 are turned, the first pull-up voltage line RT01 is connected with the second pull-up voltage line RT02 and there is no difference in voltage drop therebetween. The first switches 711-713 may include switches more that one and the control signals CS1-CS3 may be the same or different each other. That is, it is determined how many first switches are used by directly adjusting the number of switches or adjusting the number of control signals to be used.

The second switches 721-723 connect first and second pull-down voltage lines SB1 and SB2 with each other in response to control signals CS4-CS6. When the second switches 721-723 are turned, the first pull-down voltage line SB1 is connected with the second pull-down voltage line SB2 and there is no difference in voltage drop therebetween. The second switches 721-723 may include switches more that one and the control signals CS4-CS6 may be the same or different each other. That is, it is determined how many second switches are used by directly adjusting the number of switches or adjusting the number of control signals to be used similar to the first switches.

To address the concern described above, the first and second switches 711-713 and 721-723 are controlled to be turned on at the write operation of the semiconductor memory device. At this time, sine the semiconductor memory device has a plurality of signals to indicate the write operation or a read operation, the control signals CS1-CS6 can be generated by using such a plurality of signals.

In the embodiment of the present invention, the pull-up power supply circuit 730 and the pull-down power supply circuit 740 may be implemented with PMOS and NMOS transistors, respectively. Thus, during the amplification operation of the bit line sense amplifiers 710 and 720, a signal SAP changes to a low level and a signal SAN changes to a high level so that transistors T1 and T2 are turned on.

In addition, the pull-up power supply circuit 730 may be implemented with plural transistors T1_1 and T1_2 to supply a power supply voltage VDD and a core voltage VCORE when an overdriving scheme is applied. According to the overdriving scheme, the power supply voltage VDD is supplied to a pull-up voltage line RTO during the initial amplification operation, and then the core voltage VCORE is supplied to the pull-up voltage line RTO. Accordingly, during the amplification operation of the bit line sense amplifiers 710 and 720, a signal SAP1 changes to a low level first and then a signal SAP2 changes to a low level.

At this time, the first and second pull-up voltage lines RT01 and RT02 can be controlled to be separated with each other during the initial amplification operation, i.e., an overdriving period. The first switches 711-713 are turned off during the initial amplification operation of the bit line sense amplifiers 710 and 720, and then turned on. The control signals CS1-CS3 can be generated by using a signal indicating the initial amplification operation. For example, since the signal SAP1 is activated during the initial amplification operation of the bit line sense amplifiers 710 and 720, the control signals CS1-CS3 can be generated in response to the signal SAP1.

The first and second pull-down voltage lines SB and SB can be also controlled to be separated with each other during the initial amplification operation, i.e., an overdriving period. The second switches 721-723 are turned off during the initial amplification operation of the bit line sense amplifiers 710 and 720, and then turned on. The control signals CS4-CS6 may be generated in response to the signal SAP1.

In the above-described embodiments, the power supply voltage VDD and the core voltage VCORE may be used as the pull-up voltage of the sense amplifier, alternatively. In any case, as the voltage lines for the inverter pair within the sense amplifier are separated from each other, reduction of noise and voltage drop may be obtained. As a result, it is possible to improve the characteristic of the sense amplifier.

In accordance with exemplary embodiments of the present invention, the voltage lines configured to supply a voltage to two inverters composing the sense amplifier are separated. Therefore, signals for the data of a cell storing island pattern data may be amplified more strongly, which makes it possible to increase the sensing margin of the island pattern data.

When the overall sensing margin of the memory device is determined by the sensing margin of island pattern data which normally represents the worst sensing margin, the sensing margin of the island pattern data according to an exemplary embodiment of the present invention is increased to improve the overall sensing margin of the memory device.

In addition, the voltage lines are controlled to be connected in the write operation of the semiconductor memory device, so as to improve the write recovery time tWR.

While the present invention has been described with respect to the specific embodiments, it will be apparent to those skilled in the art that various changes and modifications may be made without departing from the spirit and scope of the invention as described in the following claims.

What is claimed is:

1. A sense amplifier comprising:
a first inverter having an input terminal connected to a bit line and an output terminal connected to a bar bit line; and
a second inverter having an input terminal connected to the bar bit line and an output terminal connected to the bit line,
wherein the first and second inverters are configured to receive a pull-up voltage through different pull-up voltage lines, respectively.

2. The sense amplifier of claim 1, wherein the first and second inverters are configured to receive a pull-down voltage through different pull-down voltage lines, respectively.

3. The sense amplifier of claim 1, wherein the first inverter is configured to receive the pull-up voltage from a first pull-up voltage line and the second inverter is configured to receive the pull-up voltage from a second pull-up voltage line, the first and second pull-up voltage lines being commonly connected to a pull-up power supply circuit and supplying the pull-up voltage through different paths.

4. The sense amplifier of claim 2, wherein the first inverter is configured to receive the pull-down voltage from a first pull-down voltage line and the second inverter is configured to receive the pull-down voltage from a second pull-down voltage line, the first and second pull-down voltage lines being commonly connected to a pull-down power supply circuit and supplying the pull-down voltage through different paths.

5. The sense amplifier of claim 2, wherein the first inverter is configured to receive the pull-up voltage from a first pull-up voltage line and the second inverter is configured to receive the pull-up voltage from a second pull-up voltage line, the first and second pull-up voltage lines being commonly connected to a pull-up power supply circuit and supplying the pull-up voltage through different paths, and
the first inverter is configured to receive the pull-down voltage from a first pull-down voltage line and the second inverter is configured to receive the pull-down voltage from a second pull-down voltage line, the first and second pull-down voltage lines being commonly connected to a pull-down power supply circuit and supplying the pull-down voltage through different paths.

6. The sense amplifier of claim 3, wherein the first and second pull-up voltage lines are connected to the pull-up power supply circuit through different contacts.

7. The sense amplifier of claim 3, wherein the pull-up power supply circuit comprises a PMOS transistor configured to supply the pull-up voltage to the first and second pull-up voltage lines, and the first and second pull-up voltage lines are connected to a drain of the PMOS transistor through different contacts.

8. The sense amplifier of claim 7, wherein the PMOS transistor has a fingering structure, the first pull-up voltage line is connected to the drain of the PMOS transistor through a plurality of first contacts, and the second pull-up voltage line is connected to the drain of the PMOS transistor through a plurality of second contacts.

9. The sense amplifier of claim 3, wherein the pull-up power supply circuit comprises a plurality of PMOS transistors configured to supply the pull-up voltage to the first and second pull-up voltage lines, at least one of the PMOS transistors has a drain connected to the first and second pull-up voltage lines through different contacts, and at least one of the PMOS transistors has a drain connected to the first and second pull-up voltage lines through a same contact.

10. The sense amplifier of claim 4, wherein the first and second pull-down voltage lines are connected to the pull-down power supply circuit through different contacts.

11. The sense amplifier of claim 4, wherein the pull-down power supply circuit comprises an NMOS transistor configured to supply the pull-down voltage to the first and second pull-down voltage lines, and the first and second pull-down voltage lines are connected to a drain of the NMOS transistor through different contacts.

12. The sense amplifier of claim 11, wherein the NMOS transistor has a fingering structure, the first pull-down voltage line is connected to the drain of the NMOS transistor through a plurality of first contacts, and the second pull-down voltage line is connected to the drain of the NMOS transistor through a plurality of second contacts.

13. The sense amplifier of claim 4, wherein the pull-down power supply circuit comprises a plurality of NMOS transistors configured to supply the pull-down voltage to the first and second pull-down voltage lines, at least one of the NMOS transistors has a drain connected to the first and second pull-down voltage lines through different contacts, and at least one of the NMOS transistors has a drain connected to the first and second pull-down voltage lines through a same contact.

14. A sense amplifier comprising:
a first inverter having an input terminal connected to a bit line and an output terminal connected to a bar bit line; and
a second inverter having an input terminal connected to the bar bit line and an output terminal connected to the bit line,
wherein the first and second inverters are configured to receive a pull-down voltage through different pull-down voltage lines, respectively.

15. The sense amplifier of claim 14, wherein the first inverter is configured to receive the pull-down voltage from a first pull-down voltage line and the second inverter is configured to receive the pull-down voltage from a second pull-down voltage line, the first and second pull-down voltage lines being commonly connected to a pull-down power supply circuit and supplying the pull-down voltage through different paths.

16. The sense amplifier of claim 15, wherein the first and second pull-down voltage lines are connected to the pull-down power supply circuit through different contacts.

17. A semiconductor memory device comprising:
a first sense amplifier comprising first and second inverters constituting a latch between a first bit line and a first bar bit line; and
a second sense amplifier comprising third and fourth inverters constituting a latch between a second bit line and a second bar bit line,
wherein the first and second inverters are configured to receive a voltage through different voltage lines, respectively, and the third and fourth inverters are configured to receive the voltage through different voltage lines, respectively.

18. The semiconductor memory device of claim 17, wherein the first and second sense amplifiers are arranged adjacent to each other.

19. The semiconductor memory device of claim 18, wherein the first inverter has an input terminal connected to the first bit line and an output terminal connected to the first bar bit line, and the second inverter has an input terminal connected to the first bar bit line and an output terminal connected to the first bit line.

20. The semiconductor memory device of claim 19, wherein the third inverter has an input terminal connected to the second bit line and an output terminal connected to the second bar bit line, and the fourth inverter has an input terminal connected to the second bar bit line and an output terminal connected to the second bit line.

21. The semiconductor memory device of claim 20, wherein the first inverter is coupled to a first pull-up voltage line and a first pull-down voltage line, the second inverter is coupled to a second pull-up voltage line and a second pull-down voltage line, the third inverter is coupled to the first pull-up voltage line and the first pull-down voltage line, and the fourth inverter is coupled to the second pull-up voltage line and the second pull-down voltage line.

22. The semiconductor memory device of claim 20, wherein the first inverter is coupled to a first pull-up voltage line and a first pull-down voltage line, the second inverter is coupled to a second pull-up voltage line and a second pull-down voltage line, the third inverter is coupled to the second pull-up voltage line and the second pull-down voltage line, and the fourth inverter is coupled to the first pull-up voltage line and the first pull-down voltage line.

23. The semiconductor memory device of claim 17, further comprising a pull-up power supply circuit and a pull-down power supply circuit, wherein pull-up voltage lines are connected to the pull-up power supply circuit and are configured to supply a pull-up voltage through different paths and pull-down voltage lines are connected to the pull-down power supply circuit and are configured to supply a pull-down voltage through different paths.

24. The semiconductor memory device of claim 23, wherein the pull-up voltage lines include first and second pull-up voltage lines connected to the pull-up power supply circuit through different contacts, and the pull-down voltage lines include first and second pull-down voltage lines connected to the pull-down power supply circuit through different contacts.

25. The semiconductor memory device of claim 17, wherein the different voltage lines are connected to each other in response to a control signal.

26. The semiconductor memory device of claim 25, wherein the control signal is activated in a write operation.

27. A semiconductor memory device, comprising:
a first voltage line configured to supply a voltage for driving the bit line; and
a second voltage line configured to supply a voltage for driving the bar bit line;
a switch configured to connected the first and second voltage lines to each other in response to a control signal; and
a bit line sense amplifier configured to amplify a difference in the voltage of the bit line and the voltage of the bar bit line.

28. The semiconductor memory device of claim 27, wherein the bit lines sense amplifier includes:
a first inverter having an input terminal connected to the bit line and an output terminal connected to the bar bit line; and
a second inverter having an input terminal connected to the bar bit line and an output terminal connected to the bit line,
wherein the first inverter is configured to receive the voltage supplied by the second voltage line and the second inverter is configured to receive the voltage supplied by the first voltage line.

29. The semiconductor memory device of claim 27, wherein the control signal is activated after an initial period for the bit line sense amplifier to amplify the difference.

30. The semiconductor memory device of claim 27, wherein the control signal is activated in a write operation.
